(19) United States
(12) Patent Application Publication
(10) Pub. No.: US 2013/0134114 A1
(43) Pub. Date: May 30, 2013

(54) TEST SUPPORT APPARATUS

(71) Applicants: YU-LAN LIU, Wuhan City (CN); CHANG-JUN LI, Wuhan City (CN); WEI-MIN QIN, Wuhan City (CN); YU-LIN LIU, Wuhan City (CN)

(72) Inventors: YU-LAN LIU, Wuhan City (CN); CHANG-JUN LI, Wuhan City (CN); WEI-MIN QIN, Wuhan City (CN); YU-LIN LIU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/562,774

(22) Filed: Jul. 31, 2012

(30) Foreign Application Priority Data
Nov. 29, 2011 (CN) 201110386906.8

(51) Int. Cl. H05K 7/00

(52) U.S. Cl. 211/26

(57) ABSTRACT

A test support apparatus includes a hanging plate and a holding post. The hanging plate defines a receiving hole and includes a bearing portion. The holding post is received in the receiving hole and rotatable relative to the hanging plate. The holding post includes a holding portion and a latching portion extending from the holding portion. The holding portion is secured to the bearing portion and defining a slit for a securing member to engage therein. The latching portion is rotatably engaged with edge of the receiving hole. The securing member is capable of be inserted into a threaded hole defined in a test product.

### BACKGROUND

1. Technical Field

The present disclosure relates to a test support apparatus for electronic apparatus.

2. Description of Related Art

Electronic apparatus, such as computers, often need to go through various tests, such as vibration testing or impact test. The computers define threaded holes, and the test support apparatus defines positioning holes. When the computers are tested, the computers are secured to a test support apparatus by a plurality of screws to lock into the positioning holes and the threaded holes. The threaded holes in the different model computers have different position, and position of the positioning holes in the test support apparatus can not be changed. Thus, it is costly to design different test support apparatuses corresponding to different model computers.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a test product and a test supporting apparatus.

FIG. 2 is an assembled view of the test product and the test supporting apparatus of FIG. 1.

FIG. 3 is an assembled view of three supporting members of FIG. 1.

FIG. 4 is another exploded, isometric view of the test product and the test supporting apparatus of FIG. 1.

FIG. 5 is an assembled view of the test product and the test supporting apparatus of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

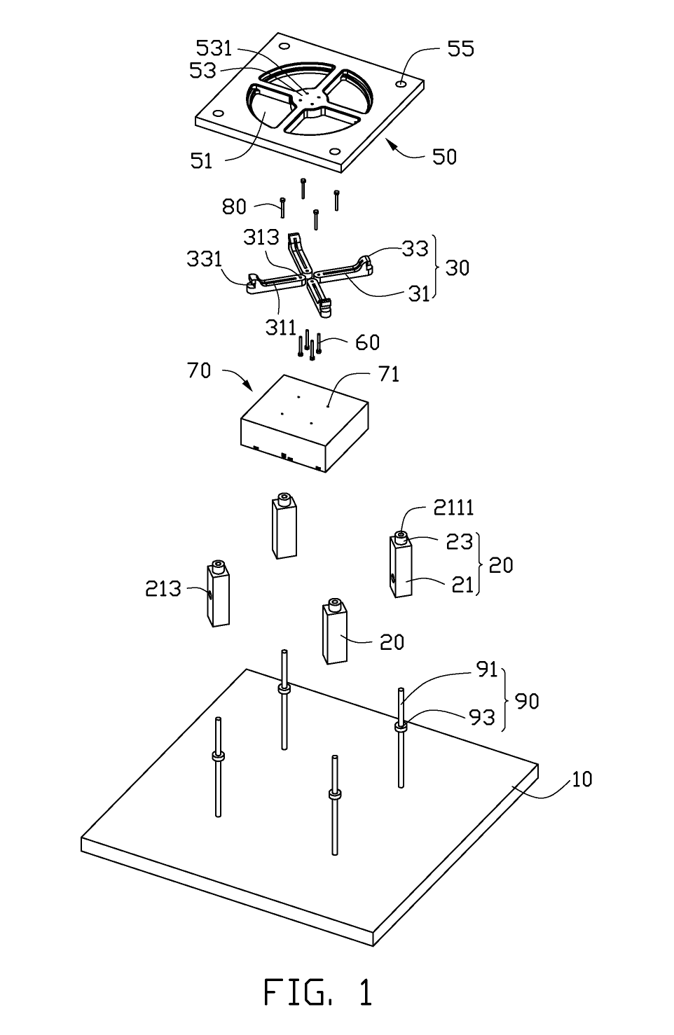

Referring to FIG. 1, a test support apparatus in accordance with an embodiment includes a platform 10, four supporting members 20, four holding posts 30, a hanging plate 50, and four mounting members 90. In one embodiment, the test support apparatus is used to secure a test product 70 with four threaded holes 71 (such as a computer enclosure), and the platform 10 is substantially a square board.

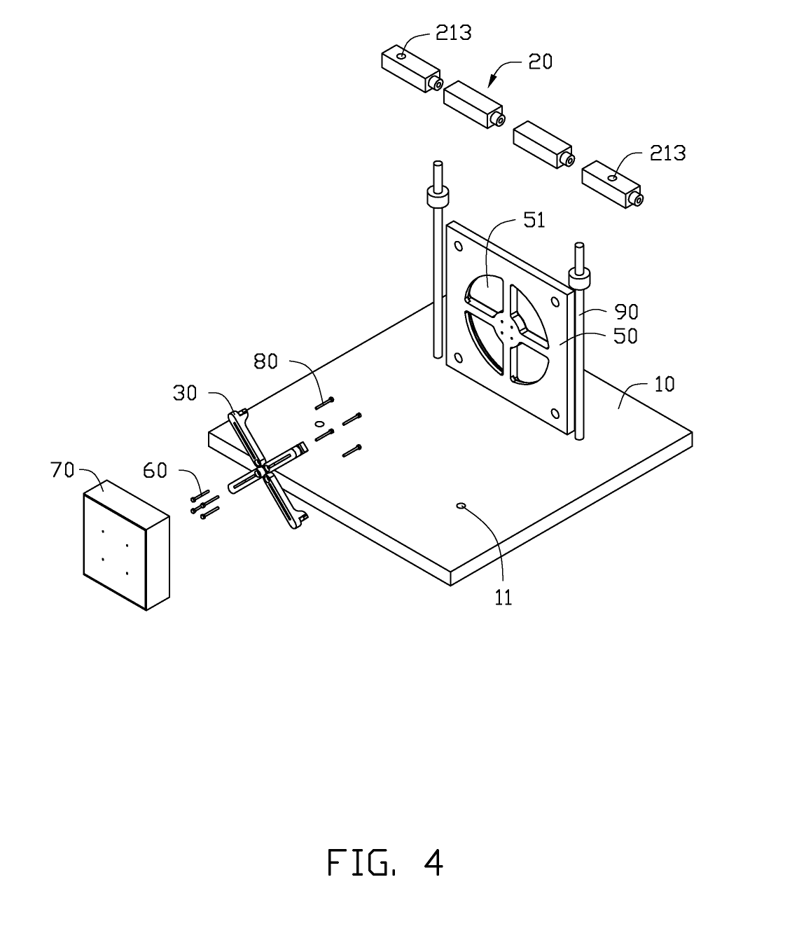

Four positioning holes 11 (shown in FIG. 4) are defined in the platform 10. In one embodiment, the four positioning holes 11 are arranged at four corner of a rectangular area.

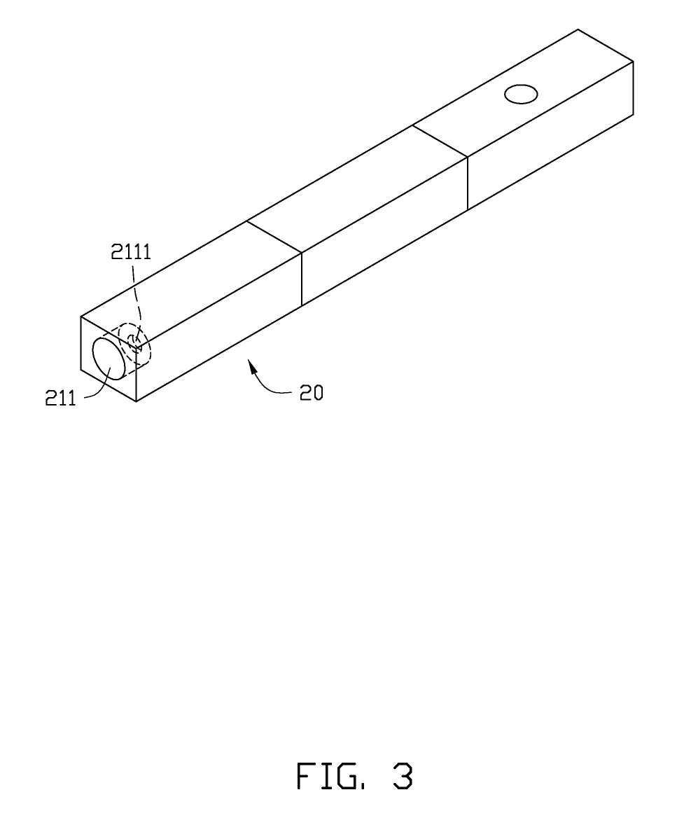

Each of the four supporting members 20 includes a supporting portion 21 and an engaging portion 23 located on one end of the supporting portion 21. Referring to FIG. 3, the supporting portion 21 defines an engaging hole 211 opposite to the engaging portion 23. An installation hole 2111, communicating with the engaging hole 211 and extending to the engaging portion 23, is defined in the supporting portion 21. Two of the four supporting members 20 further defines a through hole 213 in the supporting portion 21.

Each of four holding posts 30 includes a holding portion 31 and a latching portion 33 extending from one end of the holding portion 31. The holding portion 31 defines a slit 311 for a securing member 80 to slidably engage thereof. A holding hole 313, opposite to the latching portion 33, is defined in the holding portion 31. The slit 311 is located between the holding hole 313 and the latching portion 33. The latching portion 33 defines a mouth 331 for the hanging plate 50 to engage therein.

The hanging plate 50 defines four receiving holes 51 for receiving the four holding posts 30 and four limiting holes 55 around the four receiving holes 51. Each of the four receiving holes 51 is substantially sector-shaped. Outer sidewalls of the four receiving holes 51 cooperatively define a circle. The four receiving holes 51 form a bearing portion 53. The bearing portion 53 defines four bearing holes 531 corresponding to the holding holes 313 of the four holding posts 30. A flange 511, for engaging in the mouth 331, extends inwards from the outer sidewall of each of the four receiving holes 51.

Each of the four mounting members 90 includes a long pole 91 and a blocking portion 93 attached to the pole 91.

In assembly of the four holding posts 30, the four holding posts 30 are respectively received in the four receiving holes 51, and the four holding posts 30 are then installed one at a time in same manner, the installation of one is described as an example. The latching portion 33 of the holding post 30 is slidably engaged with the flange 511 by the mouth 331 engaging in the flange 511, and the holding hole 313 of the holding post 30 is aligned with the bearing hole 531 of the bearing portion 53. A locking member 60 is locked into the holding hole 313 and the bearing hole 531 to secure the holding post 30 to the hanging plate 50. Thus, the holding post 30 is rotatably attached to the hanging plate 50.

In assembly of the test product 70, the hanging plate 50 and the four holding posts 30 are disposed above the test product 70. Four securing members 80 are respectively inserted into the slit 311 of the four holding post 30. Each of the four securing members 80 is slidable along each the slit 311 relative to the holding posts 30, and/or the holding posts 30 is rotatable along the hanging plate 50, until each of the four securing members 80 is inserted into each of the four threaded holes 71. In one embodiment, the slit 311 has an extension direction, and the extension direction is substantially perpendicular to a tangent of rotating direction of the holding post.

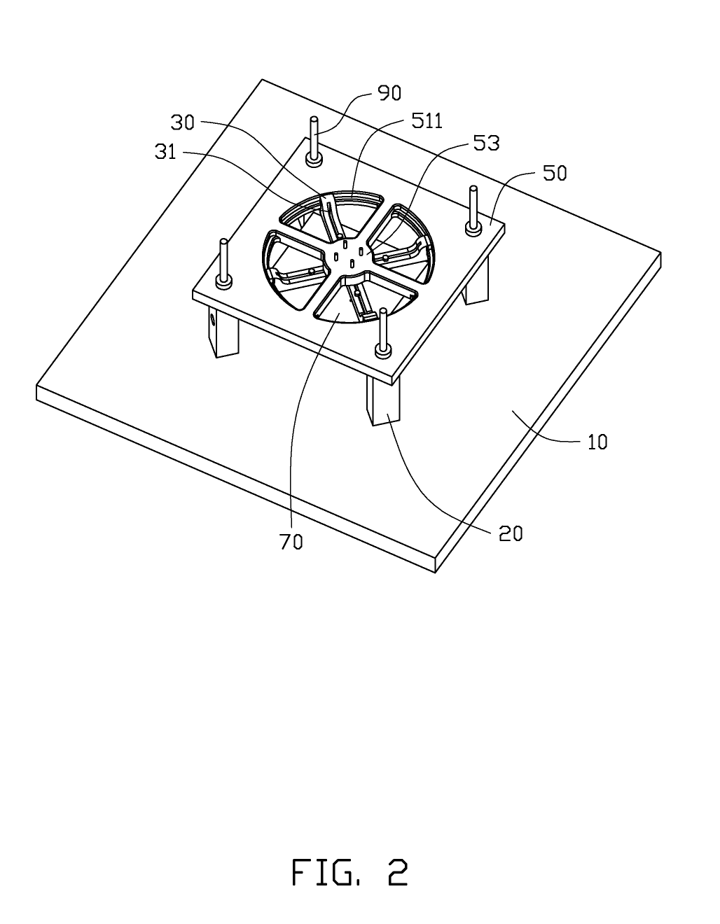

Referring to FIG. 2, when the test product 70 is tested in a horizontal direction, the four supporting members 20 are respectively located on the platform 10, and the installation hole 2111 of the four supporting members 20 are respectively aligned with the four positioning holes 111. The hanging plate 50, the test product 70, and the four holding posts 30 are placed on the four supporting members 20. The hanging plate 50 abuts the latching portion 33 of the four supporting members 20, and each of the four limiting holes 55 is aligned with the installation hole 2111 of the four supporting members 20. The pole 91 of the four mounting members 90 are respectively inserted into the limiting hole 55 of the hanging plate 50, the installation hole 2111 of the four supporting members 20 and locked into the positioning holes of the platform 10. The blocking portion 93 of the four mounting members 90 abut the hanging plate 50 for preventing the hanging plate 50 from disengaging from the platform 10. The hanging plate 50 is substantially parallel to the platform 10. The test product 70 is located between the platform 10 and the hanging plate 50 to wait for being tested.

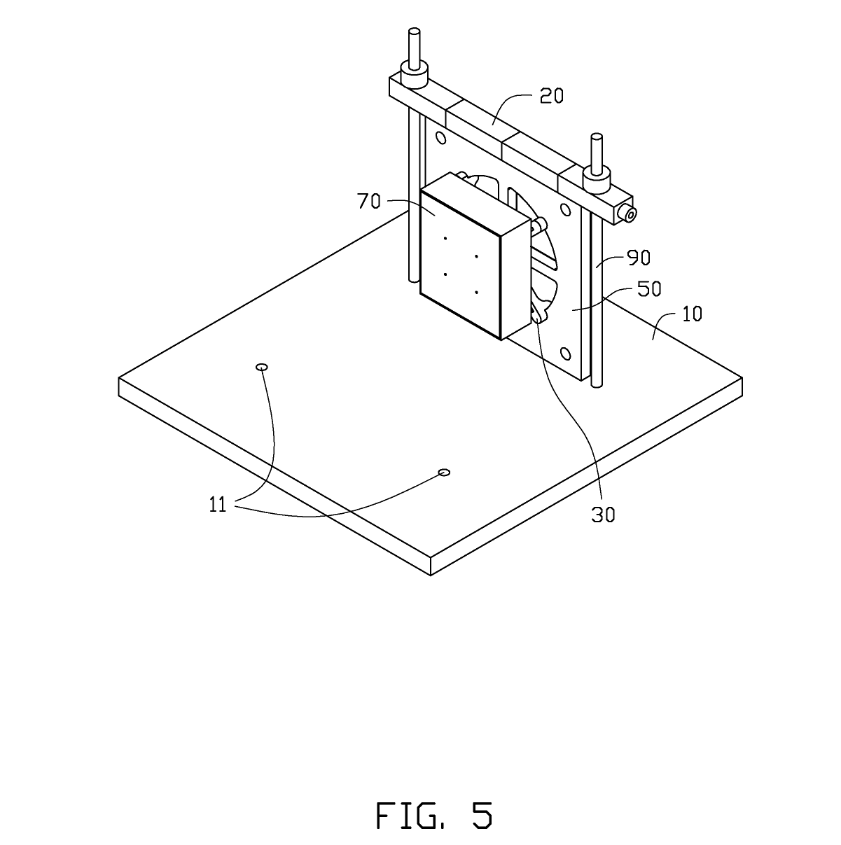

Referring to FIGS. 4 and 5, when the test product 70 is tested in a vertical direction, the four supporting members 20 are coupled one by one through engaging the engaging portion 23 into the engaging hole 211, and two of the four supporting members 20 with the through hole 213 are far away each other. A first end of the hanging plate 50 with the four holding posts 30 and the test product 70 stands on the platform 10. The four supporting members 20 abut a second end opposite to the first end of the hanging plate 50. The pole 91 of two of the four mounting members 90 are respectively inserted into the through hole 213 of the two of the four supporting members 20 and then locked into the positioning hole 11 of the platform 10. The blocking portions 93 of the two mounting members 90 abut the two supporting members 20 to press the hanging plate 50 on the platform 10. The hanging plate 50 is substantially perpendicular to the platform 10. The test product 70 is located on one side of the hanging plate 50 to wait for being tested.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A test support apparatus comprising:
a hanging plate, the hanging plate defining at least one receiving hole and comprising a bearing portion;
at least one holding post received in the at least one receiving hole and rotation relative to the hanging plate, the at least one holding post comprises a holding portion and a latching portion extending from the holding portion; and the holding portion secured to the bearing portion and defining a slit, and the latching portion is engaged with an edge of the receiving hole; and
a securing member slidably engaged in the slit;
wherein the securing member is capable of be inserted into a threaded hole defined in a test product .

2. The test support apparatus of claim 1, wherein the hang plate defines four receiving holes, the at least one holding post comprises four holding posts, and the four holding posts are respectively received in the four receiving holes.

3. The test support apparatus of claim 1, wherein the latching portion defines a mouth, a flange extends from a sidewall of the receiving hole, and the flange is engaged in the mouth.

4. The test support apparatus of claim 1, wherein the slit has an extension direction, and the extension direction is substantially perpendicular to an tangent of a rotating direction of the at least one holding post.

5. The test support apparatus of claim 1, further comprising four supporting members, wherein each of the four supporting members comprises a supporting portion, and an installation hole is defined in the supporting portion of each of the four supporting members.

6. The test support apparatus of claim 5, further comprising a platform with four positioning holes; wherein the four supporting members stand on the platform, the hanging plate abuts the four supporting members and defines four limiting holes; and four mounting members are in turn locked into the four limiting holes, the installation holes of the four supporting members, and the four positioning holes respectively, to secure the test product to the platform.

7. The test support apparatus of claim 6, wherein the hanging plate is substantially parallel to the platform.

8. The test support apparatus of claim 5, wherein each of the four supporting members further comprises an engaging portion extending from the supporting portion, the supporting portion defines an engaging hole, and the four supporting members are coupled one by one by engaging the engaging portion in the engaging hole.

9. The test support apparatus of claim 8, further comprising a platform with two positioning holes; wherein two of the four supporting members respectively define a through hole, the hanging plate stands on the platform, two mounting members are respectively locked into the two through holes and the two positioning holes, and the four supporting members abut the hanging plate for preventing the hanging plate from slanting relative the platform.

10. The test support apparatus of claim 9, wherein the hanging plate is substantially perpendicular to the platform.

11. A test support apparatus comprising:
a hanging plate, the hanging plate defining a receiving hole and comprising a bearing portion;
a holding post received in the receiving hole, the holding post defining a slit; a first end of the holding post is rotatably secured to the bearing portion, and a second end opposite the first end of the holding post slidably engaged with a sidewall of the receiving hole; and
a securing member slidably engaged in the slit;
wherein the securing member is capable of be inserted into a threaded hole defined in a test product.

12. The test support apparatus of claim 11, wherein the holding post comprises a holding portion, and the holding portion is rotatably secured to the bearing portion.

13. The test support apparatus of claim 12, wherein the holding post further comprises a latching portion extending from the holding portion; the latching portion defines a mouth, a flange extends from an edge of the receiving hole, and the flange is engaged in the mouth.

14. The test support apparatus of claim 11, wherein the slit has an extension direction, and the extension direction is substantially perpendicular to an tangent of rotating direction of the holding post.

15. The test support apparatus of claim 11, further comprising four supporting members and a platform, wherein the four supporting members, the hanging plate and the holding post are attachable to the platform.

16. The test support apparatus of claim 15, wherein the four supporting members stand on the platform and define an installation hole, the platform defines four positioning holes, and the hanging plate abuts the four supporting members and defines four limiting holes; four mounting members are in turn locked into the four limiting holes, the installation hole of the four supporting members, and the four positioning holes respectively to secure the test product to the platform.

17. The test support apparatus of claim 16, wherein the hanging plate is substantially parallel to the platform.

18. The test support apparatus of claim 15, wherein each of the four supporting members further comprises a supporting portion and an engaging portion extending from the supporting portion, the supporting portion defines an engaging hole, and the four supporting members are coupled one by one by engaging the engaging portion into the engaging hole.

19. The test support apparatus of claim 18, wherein the platform defines two positioning holes, two of the four supporting members respectively define a through hole, the hanging plate stands on the platform; two mounting members are respectively locked into the two through holes and the two positioning holes, and the four supporting members press the hanging plate for preventing the hanging plate from slanting relative the platform.

20. The test support apparatus of claim 19, wherein the hanging plate is substantially perpendicular to the platform.
